(19) United States
(12) Patent Application Publication
(10) Pub. No.: US 2002/0135979 A1
(43) Pub. Date: Sep. 26, 2002

(54) Two-phase cooling module and method of making the same

(75) Inventors: Kurt A. Estes, Lake Zurich, IL (US); Michael R. Edwards, Cary, IL (US)

Correspondence Address: MOTOROLA, INC., 1303 EAST ALGONQUIN ROAD, IL01/3RD, SCHAUMBURG, IL, 60196

(73) Assignee: MOTOROLA, INC

(21) Appl. No.: 09/812,807

(22) Filed: Mar. 20, 2001

(51) Int. Cl. H05K 7/20

(52) U.S. Cl. 361/688

(57) ABSTRACT

A two phase cooling module for electronic components includes the plurality of layered laminate sheets (204a-204n) interposed between a first cover (200) and second cover (202). The layered laminate sheets (204a-204n) define walls of a vapor/liquid cavity. A support member (208), non-integral with the plurality of layered laminate sheets (204a-204n), is operatively connected to at least one of the first and second covers (200,202). A method of making a two phase module includes forming the first cover, second cover, and window shaped laminate sheets by punching sheets of aluminum. The method also includes forming alignment apertures in each of the plurality of window-shaped laminate sheets, stacking the plurality of window-shaped laminate sheets on a cover using the alignment apertures, and placing the other cover on the resulting stack of window shaped laminate sheets to form an enclosure assembly defining the vapor/liquid cavity. Once the cavity is formed, the method includes brazing the enclosure assembly to attach the aluminum sheets and the support member together.

### FIELD OF THE INVENTION

The invention relates generally to cooling modules for electronic components, and more particularly to two-phase cooling modules (TPM) made with laminated sheets to form a vapor/liquid cavity.

### BACKGROUND OF THE INVENTION

Recently, with an increase in component density due to advances in electronic packaging techniques of integrated circuit elements, the density of heat generation and electronic equipment has greatly increased. As a result, the heat dissipation requirements within advanced electronic equipment have become increasingly more severe.

Air cooled systems are commonly used to cool electronic equipment. Now, efforts to shrink electronic assemblies have placed multiple high heat flux parts within close proximity to each other, exceeding the capacity of present air cooled technology.

Single phase liquid cooled systems are commonly used for cooling electronic components. Liquid cooling requires external condensing coils and/or significant plumbing requirements. Thus, liquid cooled systems are comparatively larger, heavier, and more costly.

The prior known systems for cooling avionics equipment, for example, use heat pipes. The heat pipe is a sealed thermodynamic system relying on internal evaporation and condensation cycles. It typically includes an enclosure, a wicking material lining internal walls in the enclosure, and a wicking fluid for saturating the wick. One end of the heat pipe is called the evaporator and serves to absorb heat energy. Vapor formed in an evaporator is transported to the other end of the heat pipe, called the condenser, and the heat energy is released. The liquid is returned to the evaporator through a wick structure on the inside of the heat pipe completing the process. The performance of this heat pipe is highly dependent on the operating temperature, wick dry out and internal generation of non-condensable gases.

Other cooling techniques are also known. For example, two phase cooling modules are known, such as those described, for example, in U.S. Pat. No. 5,924,482, entitled “Multi-Mode, Two Phase Cooling Module,” having as inventors Edwards et al., and owned by instant Assignee, and also U.S. Pat. No. 5,937,937, entitled “Heat Sinking Method for Removing Heat from a Plurality of Components,” having inventors Schembey et al. and owned by instant Assignee. Such two-phase cooling modules typically include a cavity that includes heat removal regions and a liquid reservoir region. For example, the cavity may be filled with a cooling liquid such as water, alcohol, perfluorinated dielectric liquid, or other phase change liquid. One or more electronic components are mounted onto an external surface of the module. Heat exchange fins are also typically mounted to an external surface of the module. As electronic components generate heat, over time the cooling liquid becomes heated to the point where it reaches a vapor phase. As the vapor rises in the cavity, it condenses along internal surfaces of the cavity. This heat exchange along with the external fins can greatly improve the heat dissipation for electronic components mounted to the external surfaces of the cavity.

Typically, such two-phase modules are made from aluminum. However, the manufacturing process typically used includes milling or machining out a portion of a block of aluminum to form the vapor/liquid cavity. Two such pieces are milled and/or one large piece is milled out with a flat cover being brazed on top of the milled portion to form the liquid/vapor cavity. Machining time is relatively expensive and increases the cost of manufacture. In addition, the material of the block of aluminum that is milled out is scrapped resulting in large amounts of wasted aluminum, also resulting in increased costs. Such two phase modules may also include a non-integral internal support member, such as lanced offset fin stock that is inserted in the interior of the liquid/vapor cavity to provide structural support since the walls of the cavity are typically on the order of 0.7 mm. thick. Lanced offset fins, as known in the art, include openings therein which allow both latitudinal and longitudinal flow of air (and hence liquid within the cavity). In addition, the surface area of the lanced offset fin stock provides a heat exchange surface within the liquid/vapor cavity. However, such milled two phase modules can be excessively high priced and lengthy to manufacture.

An alternative manufacturing technique has been used to manufacture two phase modules. For example, aluminum laminate sheets are stacked to form the liquid/vapor cavity. Typically, the laminated sheets include protrusions extending inwardly within the cavity as shown, for example, in FIGS. 1A-1C. As shown the laminate sheet 10, includes protrusions that may be uniform among all sheets that are stacked together. Alternatively, as shown in laminate sheets 12 and 14, they may have non-uniform protrusions extending inwardly but when stacked have common points of contact which form structural support and may be used, for example, for receiving threaded bosses or may be used for other purposes. Once the sheets with the protrusions are stacked, a top cover and bottom cover are used to form an enclosed liquid/vapor cavity. Subsequently, the assembly is put through a brazing process. The sheets with the protrusions may be, for example, aluminum impregnated with a braze alloy or may be brazed, as known in the art, using a brazing foil between the laminates. Such a manufacturing technique can reduce costs since the sheets with the protrusions are typically punched out which avoids the time consuming operation of milling blocks of aluminum. However, such two phase modules may still not have enough structural support. In addition, the protrusions can also result in additional wasted aluminum since the resulting interior portion of sheets is divided such that they are not typically conducive for reuse to manufacture additional two phase modules.

Accordingly, a need exists for a cost effective and structurally sound two phase module and method of making the same.

### BRIEF DESCRIPTION OF THE DRAWINGS

FIGS. 1A-1C are perspective views illustrating examples of prior art laminate sheets used to manufacture two phase modules;

FIG. 2 is an exploded view illustrating covers and a plurality of window shaped laminate sheets in accordance with one embodiment of the invention;

FIG. 3 is a cross-sectional view of an assembled two phase module in accordance with one embodiment of the invention when it is placed on a brazing fixture; and

FIG. 4 is an exploded view illustrating one embodiment of a two phase module with laminated layered sheets with a non-integral support member placed inside the liquid/vapor cavity in accordance with one embodiment of the invention.

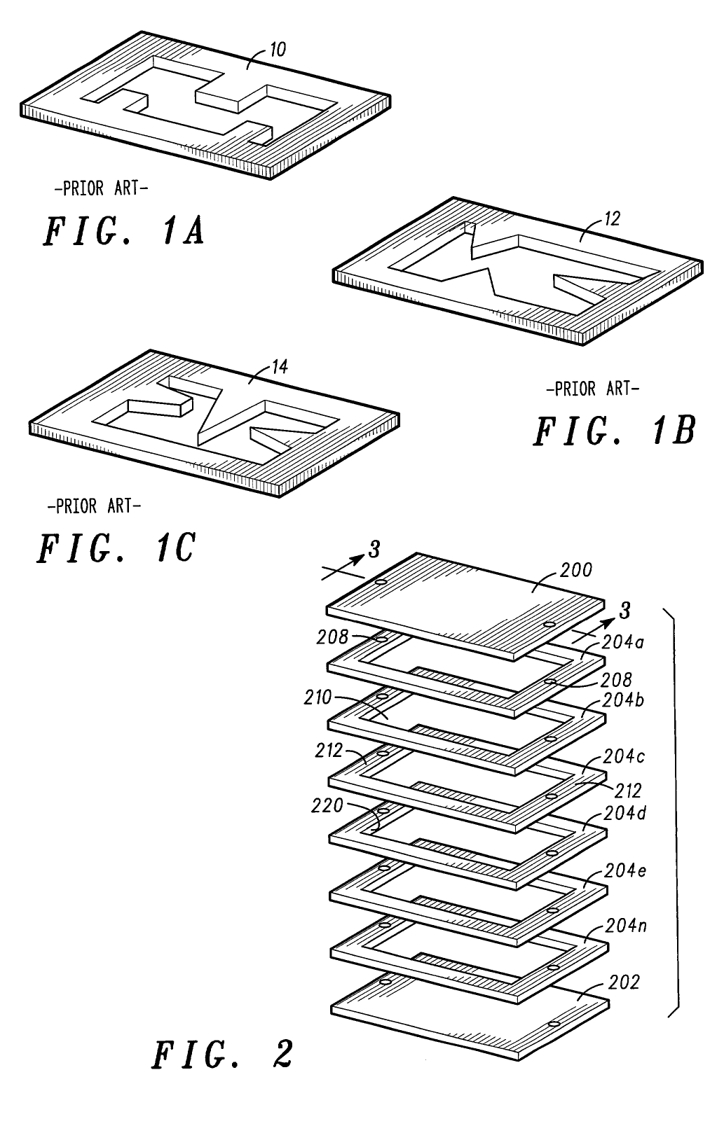

### DETAILED DESCRIPTION OF THE PREFERRED EMBODIMENT

Briefly, a two phase cooling module for electronic components includes the plurality of layered laminate sheets interposed between a first cover and second cover wherein the layered laminate sheets define walls of the vapor/liquid cavity. A support member, that is non-integral with the plurality of layered laminate sheets, is operatively connected to at least one of the first and second covers.

In one embodiment, the support member is made of lanced offset fin stock sized to fit within the resulting vapor/liquid cavity and is brazed to both the top and bottom covers. Each of the layered laminate sheets are window-shaped, and unlike conventional two phase module sheets, do not include protrusions extending into the interior of the sheet and hence the resulting liquid/vapor cavity. Also as a result, the resulting cut out portion of the window may be reused to form top and bottom covers or may be used to form window shaped laminates of smaller two phase modules, resulting in a reuse of what would normally be scrap material.

A method of making a two phase module is also described, wherein the method includes, for example, forming the first cover and second cover, such as by punching sheets of aluminum and forming the plurality of window shaped laminate sheets, such as by a punching process. The plurality of window shaped laminate sheets when layered, define an interior of a vapor/liquid cavity. The method also includes forming alignment apertures in each of the plurality of window-shaped laminate sheets, stacking the plurality of window-shaped laminate sheets on a cover using the alignment apertures, and placing the other cover on the resulting stack of window shaped laminate sheets to form an enclosure assembly defining the vapor/liquid cavity. Once the cavity is formed, the method includes brazing the enclosure assembly to attach the aluminum sheets and the support member together.

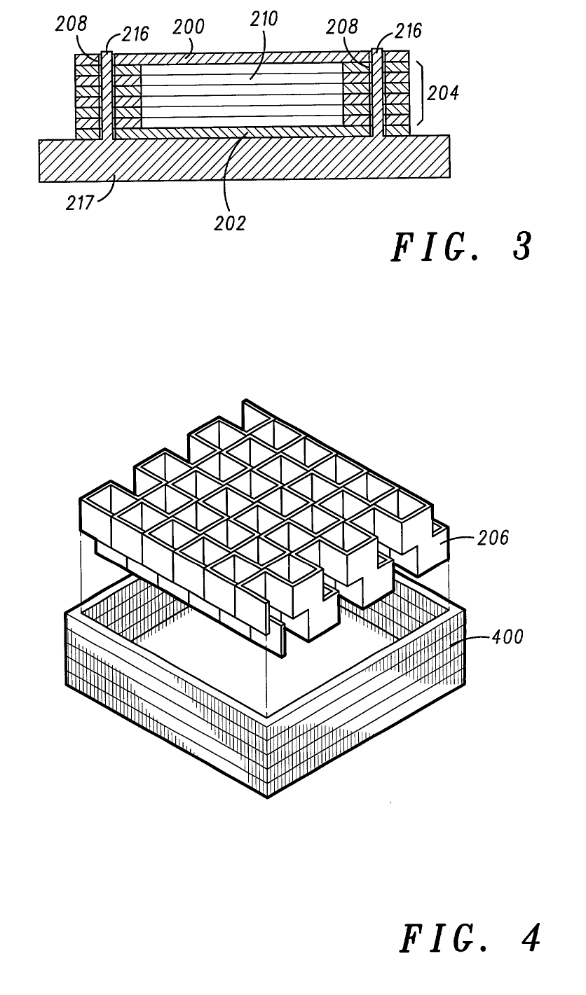

Referring to FIGS. 2-4, a cooling chamber first cover 200, such as a top cover, a cooling chamber second cover 202, such as a bottom cover, and a plurality of laminate sheets 204a-204n that define walls of a liquid/vapor cavity, form a two phase cooling module for electronic components. A support member 206, which is not integral with the plurality of laminate sheets 204a-204n, is inserted within the vapor/liquid cavity or a portion thereof, for structural support and heat transfer. The support member 206 may be inserted before or after the laminate sheets are stacked to form the housing of the two phase module.

For purposes of discussion, the material used to form the covers 200 and 202, as well as the laminate sheets 204a-204n, are made from the same material and may be, for example, 0.7 mm. thick braze stock aluminum which includes a braze alloy, as known in the art, or may be aluminum without a brazing alloy so that brazing foil sheets may be used between the laminate sheets, as known in the art. Any other suitable material and thickness may also be used as desired.

The laminate sheets 204a-204n are layered as shown in FIG. 3 (stacked) and when stacked define the vapor cavity. Each of the laminate sheets 204a-204n include alignment apertures 208 in the frame which may be holes, slots or any other suitable alignment mechanism so that they may be suitably aligned when layered. Alignment apertures are used to guide locating pins 216 on a brazing fixture 217 to provide aligned layering of the laminate sheets 204a-204n when making the module. Although not shown, the module has electrical components mounted on an external surface of the module.

Each of the laminate sheets 204a-204n have a window configuration or are window shaped meaning that they do not include protrusions extending within the interior cut out portion 210. Accordingly, a frame 212 is formed by punching out the interior cut out portion 210 as described later. It will be recognized that the window-shaped laminate sheets may be shaped as squares, rectangles, ovals, may have interior angled corners, or may be any suitable configuration to allow the insertion of a non-integral support member. In addition, the window-shaped laminate sheets allow for the reuse of the interior cut out portion 210 to form, for example, top covers or laminate cavity sheets for smaller two phase modules if desired. Preferably, although not necessary, each of the laminate sheets has a same configuration.

The support member 206, which is non-integral with the window-shaped laminate sheets 204a-204n, is preferably lanced aluminum fin stock that is suitably sized to fit within the resulting liquid/vapor cavity 400 that is formed after the window-shaped laminate sheets are stacked or layered. It will be recognized, however, that any suitable support member may also be used, such as non-integral boss structures or any other suitable structures. The lanced offset fin stock support member 206 provides advantages such as allowing liquid to flow in multiple directions due to openings within the lanced offset fin stock. In addition, the lanced offset fin stock is lightweight material and provides structural support for the two phase module. The support member 206 includes liquid flow apertures, such as holes that allow the liquid to flow through the support member in multiple directions. Suitable lanced offset fin stock is available, for example, from Robinson Fin Machines Inc., Kenton, Ohio 43326.

The two phase module in accordance with the invention may be made as follows. The first and second covers 200 and 202 may already be punched or cut to size. Preferably all sheets, namely cover 200, cover 202 and window shaped laminate sheets 204a-204n are of the same dimensions. The next step is to form the window-shaped laminate sheets 204a-204n by, for example, punching out the interior cut out portion 210 using conventional punch machines, or any other suitable technique. At the same time, or any other suitable time, the alignment apertures 208 are also formed. It will be recognized that these may be punched or, if desired, drilled, or made using any other suitable technique. Once the covers and laminate sheets have been suitably formed, the method includes cleaning and preparing the aluminum material for brazing.

The brazing fixture 212 may be used to align and stack the aluminum sheets. The method includes placing, for example, one of the covers, such as bottom cover 202 onto the brazing fixture by aligning the alignment apertures 208 with the guide pins 210. Once the cover is placed at the base of the brazing fixture, the window-shaped laminate sheets are then suitably stacked to a height that defines the desired cavity depth for the liquid/vapor cavity of the two phase module. The disclosed method herein assumes that the covers and window-shaped laminate sheets are made from the same material, namely, aluminum with impregnated brazing alloy to avoid the use of brazing foil. Once the requisite number of window-shaped laminate sheets are placed on the brazing fixture, the support member 206 is placed in a portion of or in the entire cavity defined by the inner surfaces 220 of the laminate sheets 204a-204n. It will be recognized that if desired, the support member may be placed on top of the cover before any of the alignment sheets are placed thereon.

Once the support member is placed within the cavity, the other cover is then placed on top. This results in a two phase module assembly. The assembly is then suitably clamped and brazed, as known in the art. Once brazed, additional cleanup may be used to remove resulting undesirable surfaces. Once brazed, the method includes putting a fill port through a wall of the resulting two phase module. This may be done, for example, by putting a hole and a tube through a cover or other suitable portion of the two phase module to allow the insertion of cooling liquid into the liquid/vapor cavity.

If desired, the method includes repeating the above steps to make a smaller module by reusing the interior cut out portion of the window as at least one of a cover and window shaped laminate sheet for the two phase module.

The above-disclosed methods and apparatus provide a lower cost two phase module compared to conventional two-phase modules, and also provide additional advantages by providing a non-integral support structure to allow, for example, window-shaped laminates. The window-shaped laminates can provide for the reuse of internal cut out sections for manufacture of other two-phase modules. Other advantages will be recognized by those of ordinary skill in the art.

It should be understood that the implementation of other variations and modifications of the invention in its various aspects will be apparent to those of ordinary skill in the art, and that the invention is not limited by the specific embodiments described. It is therefore contemplated to cover by the present invention, any and all modifications, variations, or equivalents that fall within the spirit and scope of the basic underlying principles disclosed and claimed herein.

What is claimed is:

1. A two phase cooling module for electronic components comprising:
a cooling chamber first cover;
a cooling chamber second cover;
a plurality of layered laminate sheets interposed between the first cover and second cover to define walls of a vapor/liquid cavity; and
a support member, non-integral with the plurality of layered laminate sheets and operatively connected to at least one of the first and second covers.

2. The module of claim 1 wherein each of the plurality of layered laminate sheets are composed of, prior to brazing, at least one of; braze stock aluminum and aluminum with brazing foil.

3. The module of claim 1 wherein each of the layered laminate sheets include alignment apertures to facilitate stacking of the layered laminate sheets.

4. The module of claim 3 wherein the alignment apertures include at least one of alignment holes and alignment slots.

5. The module of claim 1 wherein each of the plurality of layered laminate sheets are in a window configuration.

6. The module of claim 5 wherein each of the plurality of layered laminate sheets are configured in a same window configuration and wherein the window configuration includes at least one of a square window configuration, a rectangular window configuration, a non-rectangular configuration and a non-square configuration.

7. The module of claim 1 wherein the support member includes liquid flow apertures therein and is brazed to both the first cover and second cover to form structural support.

8. The module of claim 1 including electrical components mounted on an external surface of the module.

9. A two phase cooling module for electronic components comprising:
a cooling chamber first cover;
a cooling chamber second cover;
a plurality of layered laminate sheets interposed between the first cover and second cover to define walls of a vapor/liquid cavity; and
lanced offset fins, non-integral with the plurality of layered laminate sheets and operatively connected to at least one of the first and second covers.

10. The module of claim 9 wherein each of the plurality of layered laminate sheets are composed of, prior to brazing, at least one of: braze stock aluminum and aluminum with brazing foil.

11. The module of claim 9 wherein each of the layered laminate sheets include alignment apertures to facilitate stacking of the layered laminate sheets.

12. The module of claim 11 wherein the alignment apertures include at least one of alignment holes and alignment slots.

13. The module of claim 9 wherein each of the plurality of layered laminate sheets are in a window configuration.

14. The module of claim 13 wherein each of the plurality of layered laminate sheets are configured in a same window configuration and wherein the window configuration includes at least one of a square window configuration, a rectangular window configuration, a non-rectangular configuration and a non-square configuration.

15. The apparatus of claim 9 wherein the lanced fin stock is brazed to both the first cover and second cover to form structural support.

16. The apparatus of claim 9 including electrical components mounted on an external surface of the module.

17. A method for making a two phase module comprising the steps of:
forming a first cover and a second cover;
forming a plurality of window-shaped laminate sheets that when layered define an interior of a vapor/liquid cavity;
forming alignment apertures in each of the plurality of window-shaped laminate sheets;
stacking the plurality of window-shaped laminate sheets on the at least first cover using the alignment apertures;
placing the second cover on the plurality of window-shaped laminate sheets to form an enclosure assembly containing the vapor/liquid cavity; and
brazing the enclosure assembly.

18. The method of claim 17 including the step of placing a non-integral support member into the stacked plurality of window-shaped laminate sheets prior to the step of placing the second cover on the plurality of window shaped laminate sheets.

19. The method of claim 17 wherein the first cover, the second cover and the plurality of window shaped laminate sheets are formed by punching aluminum sheets.

20. The method of claim 17 wherein the step of forming the plurality of window shaped laminate sheets includes removing an interior cutout portion of a sheet to form a window and wherein the method further includes reusing the interior cut out portion of the window as at least one of a cover and window shaped laminate sheet for another two phase module.
